(19) United States
(12) Patent Application Publication
(10) Pub. No.: US 2019/0162777 A1
(43) Pub. Date: May 30, 2019

(54) Thermal forcing system for controlling a temperature of a device under test

(71) Applicant: Incavo Otax, Inc., Alameda, CA (US)

(72) Inventors: Sheung Ming John Chiang, Kowloon (HK); Glenn Chan, Fremont, CA (US)

(73) Assignee: Incavo Otax, Inc., Alameda, CA (US)

(21) Appl. No.: 15/822,129

(22) Filed: Nov. 25, 2017

(51) Int. Cl. G01R 31/28

(52) U.S. Cl. CPC G01R 31/2875

(57) ABSTRACT

A thermal forcing system for controlling a temperature of a device under test (DUT) includes a thermal plate, heater, temperature sensor, cold head, actuator, and controller. The thermal plate is thermally coupleable to the DUT. The temperature sensor senses a temperature of the thermal plate. The cold head has a temperature which is lower than that of the thermal plate. The controller is configured to: receive information of the temperature sensed by the temperature sensor; determine a temperature difference between a setpoint temperature and the temperature sensed by the temperature sensor; and command the actuator to move the cold head relative to the thermal plate or command the heater to heat the thermal plate, in response to the temperature difference, so as to facilitate adjusting the temperature of the thermal plate, and consequently the DUT, to the setpoint temperature.

### FIELD OF THE INVENTION

The present invention generally relates to the testing of electronic devices at controlled temperatures. In particular, it relates to a thermal forcing system for controlling a temperature of a device under test.

### BACKGROUND

FIG. 1 illustrates a schematic diagram of a test system for testing a Device Under Test (DUT) 200, such as an Integrated Circuit (IC) or other electronic device. A device tester 400 is electrically connected to contacts on a Printed Circuit Board (PCB) 300 through a cable 450. A socket 100, which is adapted to receive the DUT 200, is mounted on the PCB 300 to electrically connect the contacts on the PCB 300 to corresponding contacts on the DUT 200. When the DUT 200 is coupled to the socket 100, the device tester 400 provides electrical stimuli through the socket 100 to input contacts of the DUT 200 and receives electrical responses for analysis from output contacts of the DUT 200 through the socket 100. As a result of the analysis, the device tester 400 may sort the DUT 200 into different categories, such as pass or fail, according to device specifications, and/or sort the DUT 200 into different grades, such as by measured response characteristics.

In addition to testing the DUT 200 at ambient temperature, the DUT 200 may be tested at selected temperatures over a specified temperature range that includes extreme temperatures for reliability and/or burn-in tests. In order to test the DUT 200 over such a temperature range, it is necessary to either cool down or heat up the DUT 200 while it is being tested by the device tester 400.

FIG. 2 illustrates a schematic diagram of the test system of FIG. 1 with the addition of a Thermal Control Unit (TCU) 500, which makes physical and thermal contact with the DUT 200, for controlling the temperature of the DUT 200 while it is being tested by the device tester 400. The TCU 500 includes one or more temperature sensors 560 that sense a temperature of a bottom surface of the TCU 500 which makes physical and thermal contact with an adjoining top surface of the DUT 200 while testing the DUT 200. The temperature of the top surface of the DUT 200 is thus cooled down or heated up to the temperature of the bottom surface of the TCU 500 through the adjoining contact surfaces. A controller 600 is electrically connected to the TCU 500 for controlling its operation so that the temperature sensed by the one or more temperature sensor(s) 560 is driven to a setpoint temperature which is specified by an operator interacting with input features of the controller 600.

The process of forcing the temperature of the DUT 200 to the extreme ends of its specified temperature operating range is referred to as temperature forcing. Therefore, a system capable of temperature forcing is referred to as a temperature forcing system or a thermal forcing system.

FIG. 3 illustrates, as an example, a block diagram depicting certain characteristics of prior art thermal forcing systems for controlling the temperature of the DUT 200. In general, prior art thermal forcing systems comprise three major components. The first component is the TCU 500, the second component is the controller 600, and the third component is a refrigeration loop 610.

The TCU 500 comprises an evaporator 524 which is coupled to the refrigeration loop 610 to form a refrigeration system, a thermal plate 526 which is the bottom surface of the TCU 500 that makes physical and thermal contact with the DUT 200 during its testing, temperature sensor(s) 560 which sense the temperature of the thermal plate 526, and a Thermoelectric Cooler (TEC) 525 which is disposed between the evaporator 524 and the thermal plate 526.

The TEC 525 is a Peltier device having two faces. One of the faces is in thermal contact with the evaporator 524 and the other is in thermal contact with the thermal plate 526. The polarity and magnitude of the applied current to the TEC 525 creates a temperature difference between the two faces causing heat flow from one face to the other. Thus, when the thermal plate 526 is to absorb heat from the DUT 200, the controller 600 may control the amount of heat being absorbed by the evaporator 524 from the thermal plate 526 by controlling the polarity and magnitude of the applied current to the TEC 525. On the other hand, when the thermal plate 526 is to provide additional heat to the DUT 200, the controller 600 may control the amount of additional heat by providing a different polarity and appropriate magnitude of the applied current to the TEC 525, so that the heat flow is reversed to heat the thermal plate 526. This heat flow includes the power dissipation of the TEC 525 and the heat being absorbed from the other face of the TEC 525.

Although use of the TEC 525 may be a convenient means for controlling the temperature of the DUT 200 as described above, such Peltier devices are generally considered to be not very efficient and their design limitation on heat transfer capacity limits the maximum cooling capacity of the system.

As an alternative, or supplement, to using the TEC 525 for heating the thermal plate 526, a heater 522 may be included in the TCU 500 to heat the thermal plate 526 under the control of the controller 600. When the heater 522 is provided in addition to the TEC 525, it is normally preferred to turn off the TEC 525 and turn on the heater 522 for heating the thermal plate 526. Reversing current to the TEC 525, so that heat flow is reversed to heat the thermal plate 526, will shorten the life of the TEC 525 and extra power switches (not shown) are required in the implementation to reverse the current. Therefore, to heat the thermal plate 526, it is generally easier and more effective to just power up the heater 522.

As another alternative to using the TEC 525 for controlling the absorption of heat from the thermal plate 526, certain prior art thermal forcing systems have controlled the refrigerant flow rate in the refrigeration system. However, such an approach may result in undesirable time delays in adjusting the temperature of the thermal plate 526. Therefore, although such control may be suitable for initially forcing the temperature of the thermal plate 526 to the extreme cold end of the temperature operating range of the DUT 200, it may not be suitable for maintaining the temperature of the DUT 200 at the extreme cold end in response to changes in the heat generated by the DUT 200 during its testing due to such time delay.

### BRIEF SUMMARY

The embodiments of the invention are summarized by the claims that follow below.

### BRIEF DESCRIPTION OF THE DRAWINGS

FIG. 1 illustrates a schematic diagram of a prior art test system for testing a device under test.

FIG. 2 illustrates a schematic diagram of a prior art test system including a prior art thermal forcing system for controlling a temperature of a device under test.

FIG. 3 illustrates a block diagram of a prior art thermal forcing system for controlling the temperature of a device under test.

FIG. 4 illustrates a schematic diagram of a test system including a thermal forcing system, utilizing aspects of the present invention, for controlling a temperature of a device under test.

FIG. 5 illustrates a perspective view of a thermal forcing system, utilizing aspects of the present invention, for controlling a temperature of a device under test.

FIG. 6 illustrates a cross-sectional view of a thermal control unit, utilizing aspects of the present invention, that is usable in a thermal forcing system utilizing aspects of the present invention.

FIG. 7 illustrates a block diagram including components of a thermal forcing system utilizing aspects of the present invention.

FIG. 8 illustrates a block diagram including interacting portions of a control box and a thermal control unit for implementing a heating system in a thermal forcing system utilizing aspects of the present invention.

FIG. 9 illustrates a block diagram including interacting portions of a control box and a thermal control unit for implementing a refrigeration system in a thermal forcing system utilizing aspects of the present invention.

FIG. 10 illustrates a block diagram including interacting portions of a control box and a thermal control unit for actuating a pneumatic actuator in the thermal control unit as part of a thermal forcing system utilizing aspects of the present invention.

FIG. 11 illustrates a block diagram of a controller usable in a thermal forcing system utilizing aspects of the present invention.

FIG. 12 illustrates a block diagram of a first embodiment of technology usable for implementing a controller in a thermal forcing system utilizing aspects of the present invention.

FIG. 13 illustrates a block diagram of a second embodiment of technology usable for implementing a controller in a thermal forcing system utilizing aspects of the present invention.

FIG. 14 illustrates a block diagram of a third embodiment of technology usable for implementing a controller in a thermal forcing system utilizing aspects of the present invention.

FIG. 15 illustrates a thermal conductance versus applied force relationship which is usable in a thermal forcing system utilizing aspects of the present invention.

FIG. 16 illustrates a partial cross-sectional view of adjoining surfaces of a cold head and a thermal plate, which are usable in a thermal forcing system utilizing aspects of the present invention.

FIG. 17 illustrates a partial cross-sectional view of adjoining surfaces of a cold head and a thermal plate coated with a thermal interface material, which are usable in a thermal forcing system utilizing aspects of the present invention.

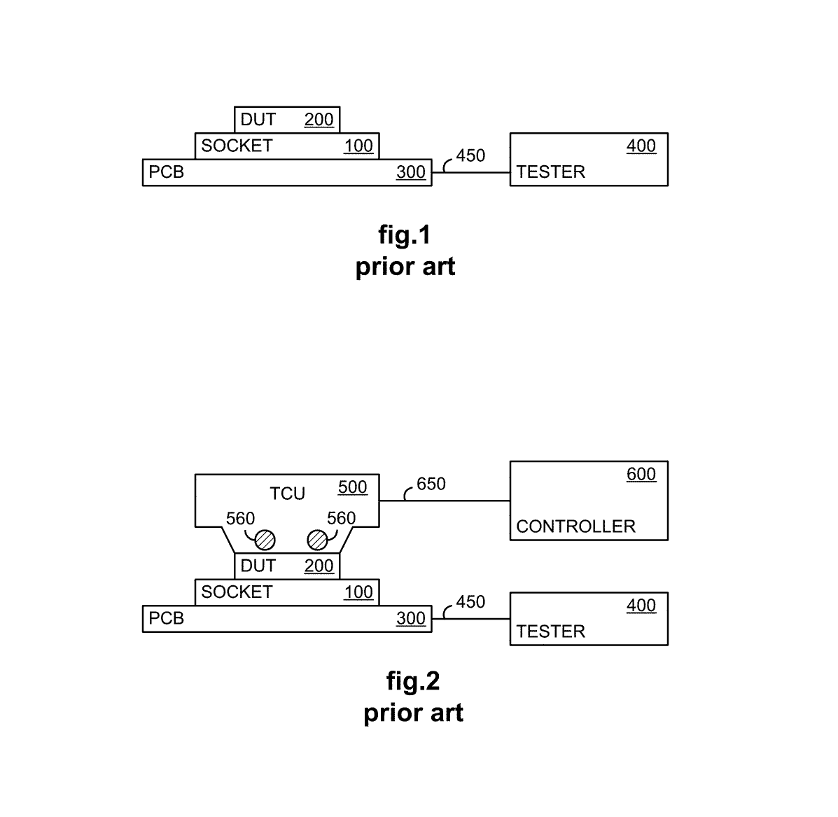

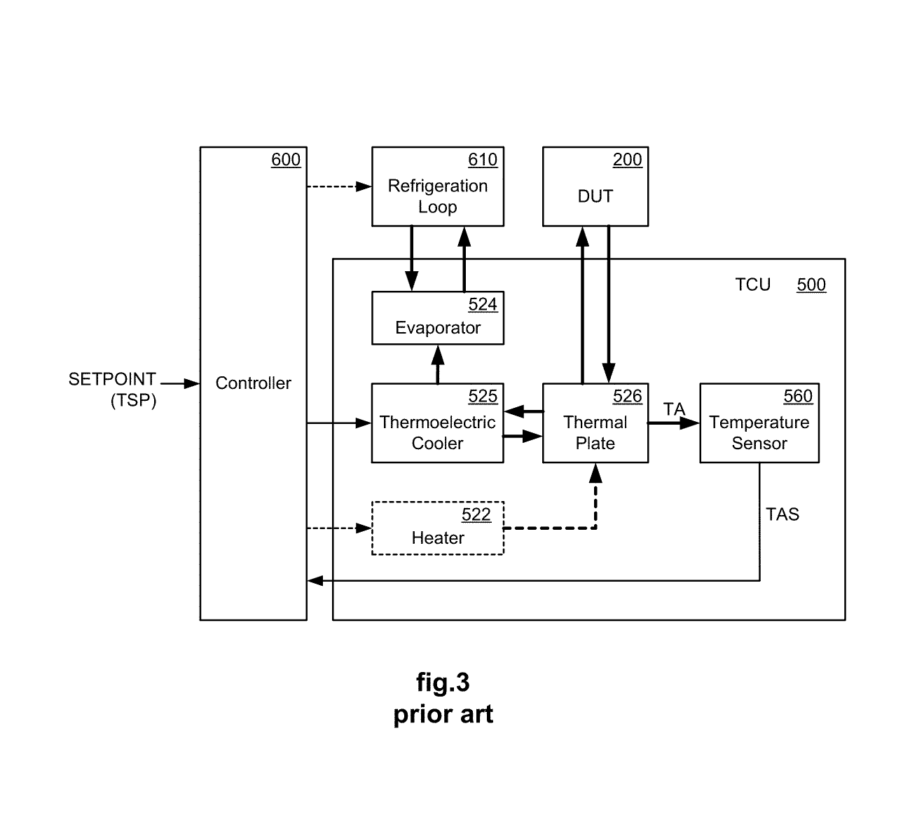

### DETAILED DESCRIPTION

In the following description, spatially relative terms—such as “top”, “bottom”, “beneath”, “below”, “lower”, “above”, “upper”, “proximal”, “distal”, and the like—may be used to describe one element's or feature's relationship to another element or feature as illustrated in the figures. These spatially relative terms are intended to encompass different positions (i.e., locations) and orientations (i.e., rotational placements) of a device in use or operation in addition to the position and orientation shown in the figures. For example, if a device in the figures is turned over, elements described as “below” or “beneath” other elements or features would then be “above” or “over” the other elements or features. Thus, the exemplary term “below” can encompass both positions and orientations of above and below. A device may be otherwise oriented (rotated 90 degrees or at other orientations) and the spatially relative descriptors used herein interpreted accordingly.

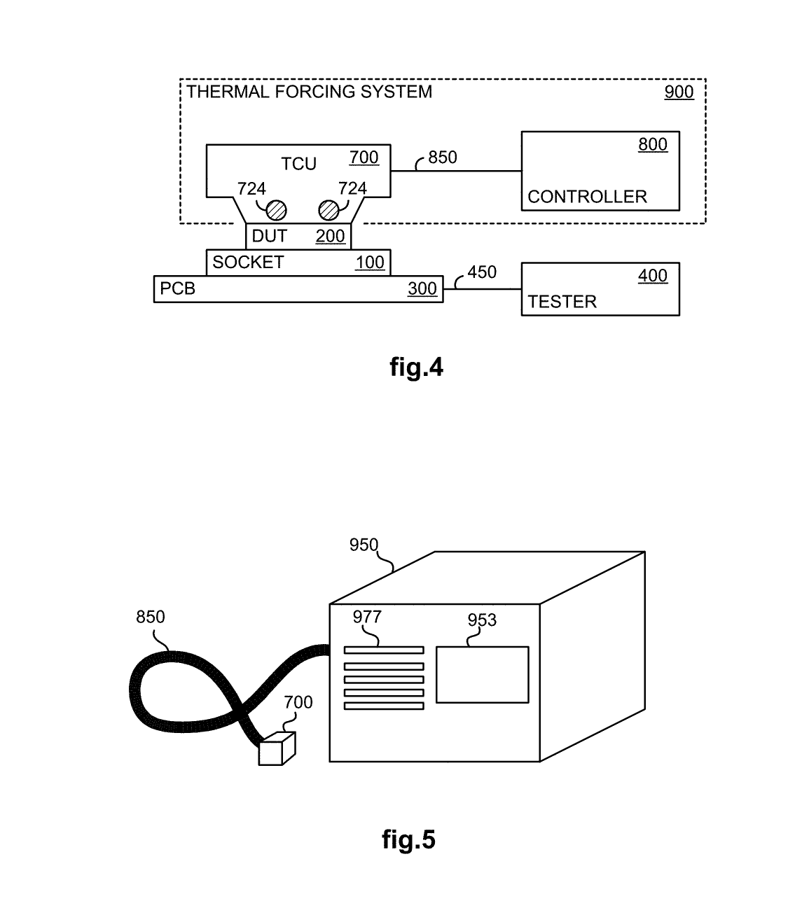

FIG. 4 illustrates, as an example, a schematic diagram of a test system that includes a thermal forcing system 900 for controlling a temperature of a Device Under Test (DUT) 200, such as an Integrated Circuit (IC) device or other electronic device. The test system tests the DUT 200 in a conventional manner by the device tester 400 providing electrical stimuli through the cable 450 and the socket 100 to input contacts of the DUT 200 and receiving electrical responses for recording and/or analysis from output contacts of the DUT 200 through the socket 100 and the cable 450.

During testing of the DUT 200, the thermal forcing system 900 controls the temperature of the DUT 200, as sensed by one or more temperature sensors 724, so that the temperature of the DUT 200 is raised to, lowered to, and/or maintained at a setpoint temperature. The thermal forcing system 900 comprises a Thermal Control Unit (TCU) 700 and a controller 800, which communicate through input/output lines 850. The setpoint temperature is selectable by an operator interacting with input features of the thermal forcing system 900.

FIG. 5 illustrates, as an example, a perspective view of the thermal forcing system 900. A control box 950 houses the controller 800, as well as other components of the thermal forcing system 900 as described below. A Liquid Crystal Display (LCD) touchscreen 953 is provided on a front panel of the control box 950 to facilitate a Graphical User Interface (GUI) that provides a means for the operator to interact with the thermal forcing system 900. For example, the GUI may display touch-sensitive items such as command menus, icons, keyboards, and numerical keypads. Alternatively, other conventional means for the operator to interact with the thermal forcing system 900 are also contemplated as being fully within the scope of the invention(s) claimed herein. Grills 977 are also provided on the front panel of the control box 950 for air circulation into and out of the control box 950. Input/output lines 850 provide connections between interacting components in the control box 950 and the TCU 700, as further described below.

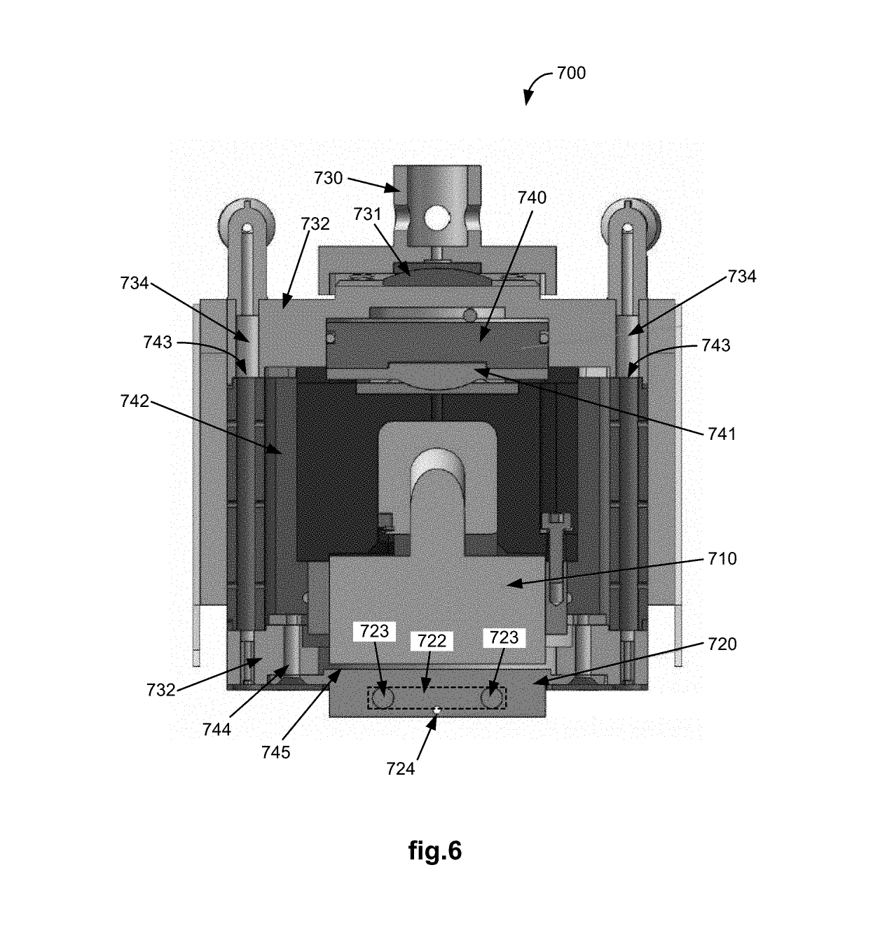

FIG. 6 illustrates, as an example, a cross-sectional view of the TCU 700. Starting with the bottom of the TCU 700, a thermal plate 720 includes an electrical heater 722 and at least one temperature sensor 724 for sensing a temperature of a bottom surface of the thermal plate 720. The thermal plate 720, heater 722, and temperature sensor(s) 724 are thermally coupled to each other, so that heat is transferable between them. The electrical heater 722 comprises electrical cartridge heaters 723 which are resistance heated by passing electrical current through them.

When the DUT 200 is being tested by the test system, a top surface of the DUT 200 makes physical contact with the bottom surface of the thermal plate 720, so that heat is transferable between them. Thus, the temperature being sensed by the temperature sensor 724 is indicative of the temperature of the DUT 200 after the respective temperatures of the bottom surface of the thermal plate 720 and the top surface of the DUT 200 stabilize to the same temperature.

The thermal plate 720 is secured in a conventional manner, such as by a fastener, to a bottom of a housing 732 so that the thermal plate 720 moves when the housing 732 moves. Inside the housing 732 are two or more cylindrical poles 734 which extend vertically so that top ends of the cylindrical poles 734 are attached to a top inner surface of the housing 732 and bottom ends of the cylindrical poles 734 are attached to a bottom inner surface of the housing 732. Also inside the housing 732 is a block 742 having through-holes 743 which extend vertically from the top of the block 742 to a bottom of the block 742. The cylindrical poles 734 are aligned in the through-holes 743 so that each pole 734 extends through a corresponding one of the through-holes 743. As a consequence, the block 742 may vertically slide up and down the poles 734.

Also inside the housing 732 is a cold head 710 which is secured to the block 742 so that the cold head 710 moves vertically up and down as the block 742 moves vertically up and down. The cold head 710 comprises an evaporator, which is part of a conventional refrigeration system through which a refrigerant cycles between gas and liquid phases to absorb heat.

An external actuator 730, when actuated, generates a downward force on external pusher plate 731, which in turn, generates a downward force on the housing 732. Preferably, the external actuator 730 is a pneumatic actuator having at least one piston which is pneumatically coupled to a compressed air supply through the control box 950. In this case, when the operator interacts with the thermal forcing system 900 to cause compressed air to be injected into the piston, the piston generates the downward force. By applying such downward force, the external actuator 730 causes the bottom surface of the thermal plate 720 to make and maintain physical and thermal contact with the top surface of the DUT 200 during testing of the DUT 200. Alternatively, the external actuator 730 may be a mechanism that allows the operator to manually apply a downward force on the external pusher plate 731.

An internal actuator 740 is disposed within the housing 732. The internal actuator 740, when actuated, generates a downward force on internal pusher plate 741, which in turn, generates a downward force on the block 742. Preferably, the internal actuator 740 is also a pneumatic actuator having at least one piston which receives compressed air, in response to a command to do so by the controller 800, from the compressed air supply through the control box 950. By configuring both the external and internal actuators as pneumatic actuators, a single compressed air supply may advantageously be shared by both actuators. In alternative embodiments, either or both external and internal actuators may be implemented using other conventional actuator technologies, such as electrically driven motors or hydraulic actuators.

Also disposed within the housing 732 are two or more bias springs 744, each of which is attached at one end to the bottom of block 742 and at the other end to the bottom inner surface of the housing 732, so that the bias springs 744 generate an upward force on the block 742 so as to generate a gap 745 between the bottom surface of the cold head 710 and the top surface of the thermal plate 720 when the internal actuator 740 is not being actuated.

The top surface of the thermal plate 720 is above the bottom inner surface of the housing 732. Therefore, the bias spring 744 is never completely compressed even after the bottom surface of the cold head 710 makes physical contact with the top surface of the thermal plate 720. Consequently, the bias spring 744 resists, but does not prevent the internal actuator 740 from generating an increasing downward force on the block 742 that results in increasing pressure being applied by the bottom surface of the cold head 710 against the top surface of the thermal plate 720 even after the two adjoining surfaces make physical contact with each other.

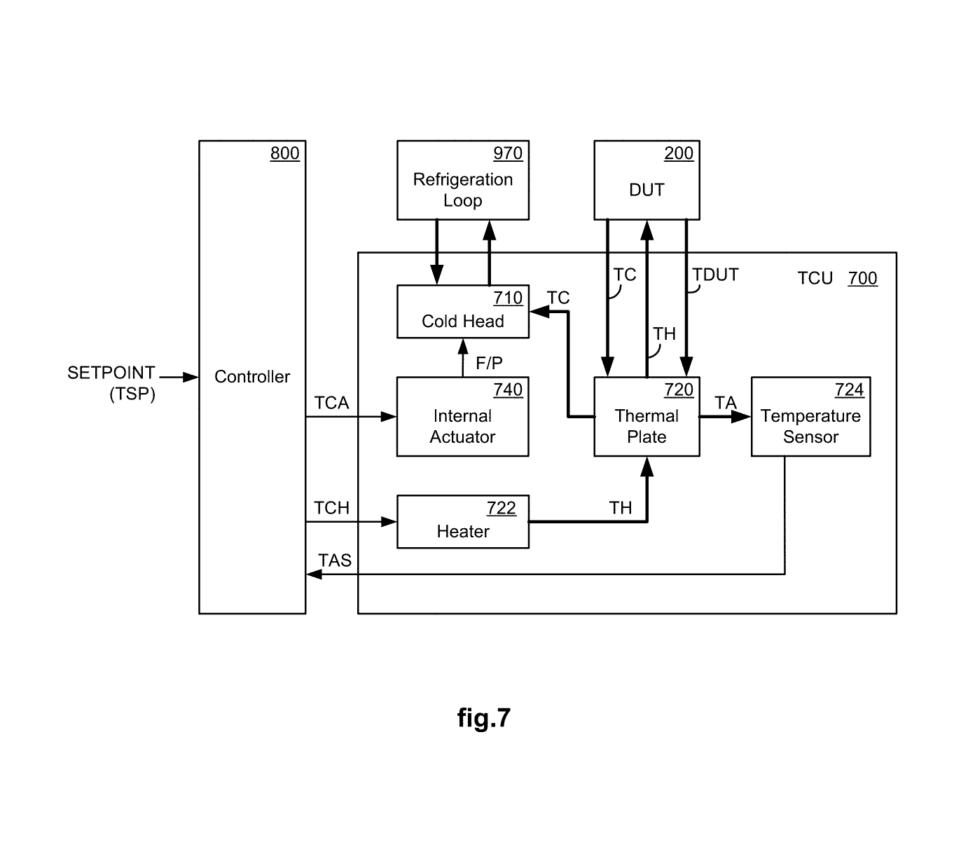

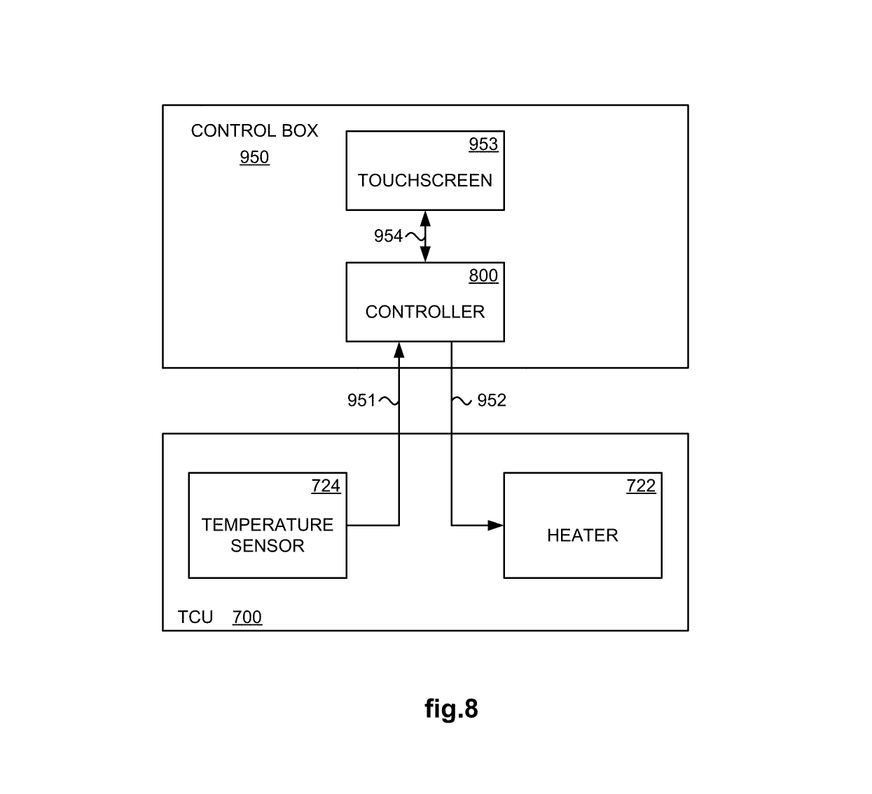

FIG. 7 illustrates, as an example, a block diagram including components of the thermal forcing system 900. The controller 800 receives information of the setpoint temperature (TSP), which was provided by an operator interacting with input features of the system 900, such as a GUI including the touchscreen 953. As shown in the example illustrated in FIG. 8, the information of the setpoint temperature (TSP) is provided to the controller 800 in digital form by the touchscreen 953 over a data bus 954 in the control box 950.

The controller 800 also receives information of a sensed temperature (TAS) from the temperature sensor 724. The received information may be a digital value, if the temperature sensor 724 includes an Analog-to-Digital (A/D) converter, wherein the digital value is preferably transmitted in a serial transmission format. Alternatively, the received information may be an analog signal which the controller 800 converts to a digital value, if the temperature sensor 724 does not include an A/D converter. In either case, the information of the sensed temperature (TAS) indicates the temperature (TA) of the bottom surface of the thermal plate 720. As shown in the example illustrated in FIG. 8, the information of the sensed temperature (TAS) is provided to the controller 800 by the temperature sensor 724 in the TCU 700 over an electrical line 951, which is one of the input/output lines 850.

The controller 800 processes the received information of the setpoint temperature (TSP) and the sensed temperature (TAS) to generate a control input (TCH) for the heater 722 and/or a control input (TCA) for the internal actuator 740. The control input (TCH) for the heater 722 is an electrical signal having a magnitude that determines the magnitude of heat generated by the heater 722. As shown in the example illustrated in FIG. 8, the control input (TCH) is provided to the heater 722 by the controller 800 over an electrical line 952, which is one of the input/output lines 850.

In order to control the temperature of the thermal plate 720, and consequently, the temperature of the DUT 200, the controller 800 controls the operation of the heater 722 and actuation of the internal actuator 740 in response to the temperature difference between the setpoint temperature (TSP) and the sensed temperature (TAS). Optionally, it may also control the temperature of the cold head 710. In the preferred embodiment, however, the temperature of the cold head 710 is automatically driven without intervention by the controller 800 to a low end temperature of the temperature testing range by the refrigeration system after the thermal forcing system 900 is turned on. The nominal temperature of the cold head 710 may be specified by the operator interacting with input features of the thermal forcing system 900, or it may be preset to a specific temperature value by the manufacturer of the thermal forcing system 900.

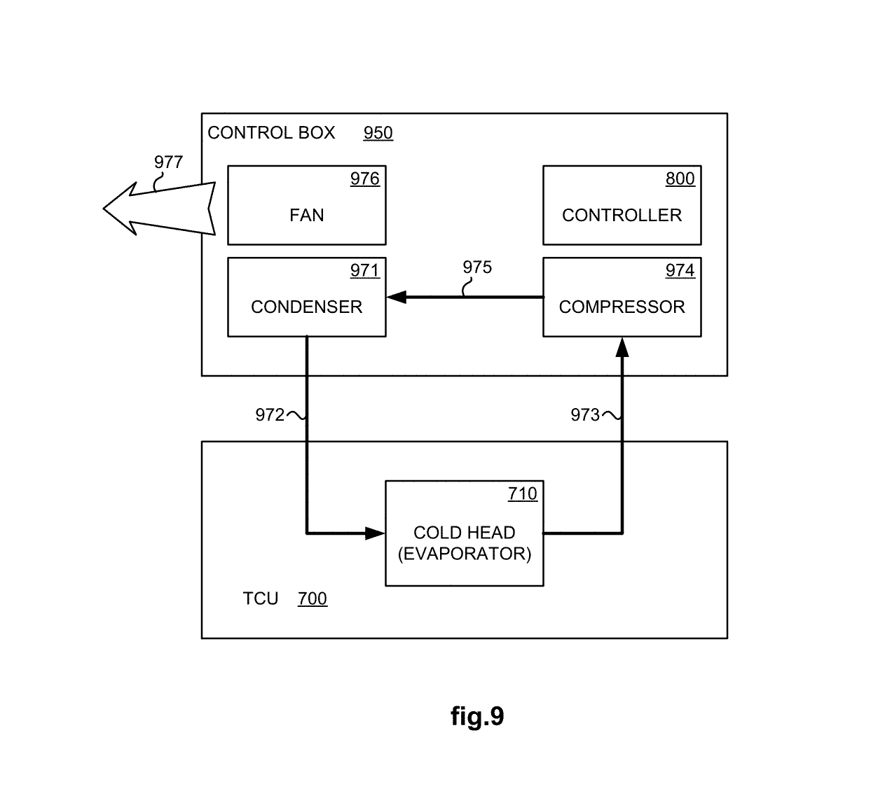

FIG. 9 illustrates, as an example, a block diagram including interacting portions of the control box 950 and the TCU 700 for implementing the refrigeration system. The refrigeration system is a conventional two-phase system in which a refrigerant cycles between gas and liquid phases to absorb and release heat. In particular, the cold head 710 comprises an evaporator which receives a refrigerant liquid from a condenser 971 in the control box 950 via a fluid line 972 and absorbs latent heat by evaporating the refrigerant liquid into a low temperature, low pressure refrigerant gas that is passed to a compressor 947 in the control box 950 via a gas line 973. Both the fluid line 972 and the gas line 973 are included in the input/output lines 850. The compressor 974 then compresses the refrigerant gas into a high temperature, high pressure refrigerant gas which is passed through gas line 975 to the condenser 971, which condenses the refrigerant gas back into a refrigerant liquid and releases the resulting heat into the air so that it may be expelled out of the control box 950 through grills 977 by a fan 976.

When the DUT 200 is to be heated up, such as towards the high end of the temperature testing range (e.g., +150° Celsius), the controller 800 increases the current being provided to the heater 722 to increase the temperature of the thermal plate 720, and preferably does not actuate the internal actuator 740 so that the cold head 710 is displaced from the thermal plate 720 by the gap 745. Conversely, when the DUT 200 is to be cooled down, such as towards the low end of the temperature testing range (e.g., −45° Celsius), the controller 800 preferably turns off the current being provided to the heater 722 and actuates the internal actuator 740 so that it generates sufficient force to cause the bottom surface of the cold head 710 to move towards, and possibly apply contact pressure against, the top surface of the thermal plate 720. As will be described below, depending upon how much the DUT 200 is to be cooled, the generated force will be sufficient to either reduce the gap between the bottom surface of the thermal plate 720 and the top surface of the DUT 200, or to cause the bottom surface of the thermal plate 720 to make physical contact to, and apply sufficient pressure against, the top surface of the DUT 200.

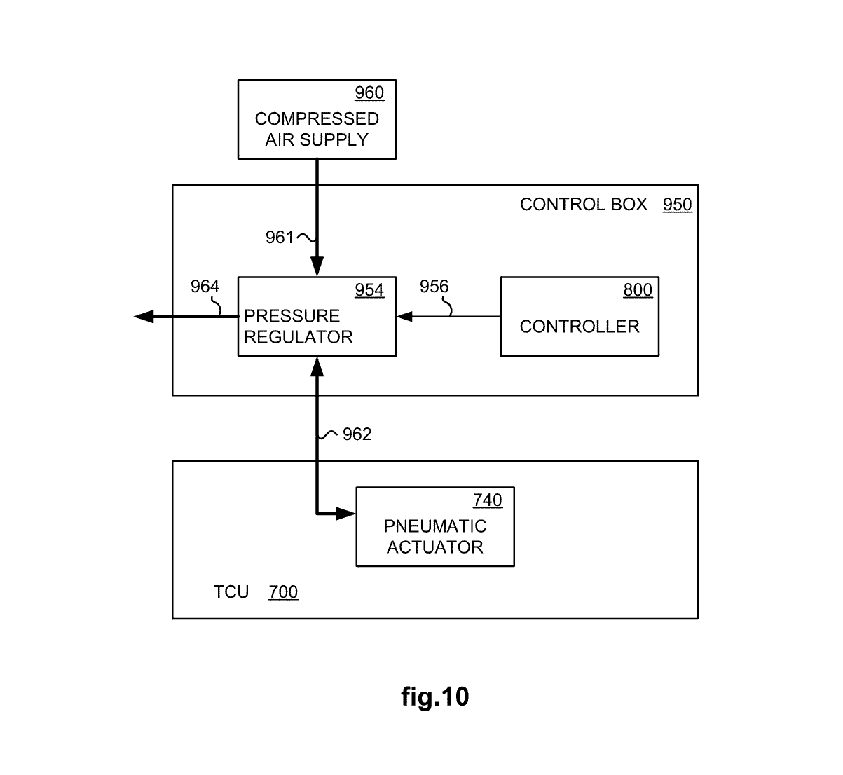

FIG. 10 illustrates, as an example, a block diagram including interacting portions of the control box 950 and the TCU 700 for actuating the internal actuator 740, which in this example is a pneumatic actuator. Included in the control box 950 is an electronic pressure regulator 954. An external compressed air supply 960 is connected to the control box 950, and in particular, to an input of the pressure regulator 954 via an air line 961. The pressure regulator 954 is electrically controllable via an electrical line 956 by the controller 800, so that the output pressure of the pressure regulator 954 is controllable by the controller 800. The pressure regulator 954 is connected to an inlet line 962 of one or more pistons of the pneumatic actuator 740, so that the controller 800 controls actuation of the pneumatic actuator 740 by controlling the output pressure of the pressure regulator 954. For example, to actuate the pneumatic actuator 740, the controller 800 commands the pressure regulator 954 to provide compressed air at a commanded pressure level to the pistons of the pneumatic actuator 740. When the pneumatic actuator 740 is not to be actuated, the controller 800 commands the pressure regulator 954 to reduce the pressure level in the pistons of the pneumatic actuator 740 to zero pressure. To do this, the pressure regulator 954 releases the compressed air in the pistons of the pneumatic actuator 740 through the inlet line 962 to an integrated release port 964 of the pressure regulator 954.

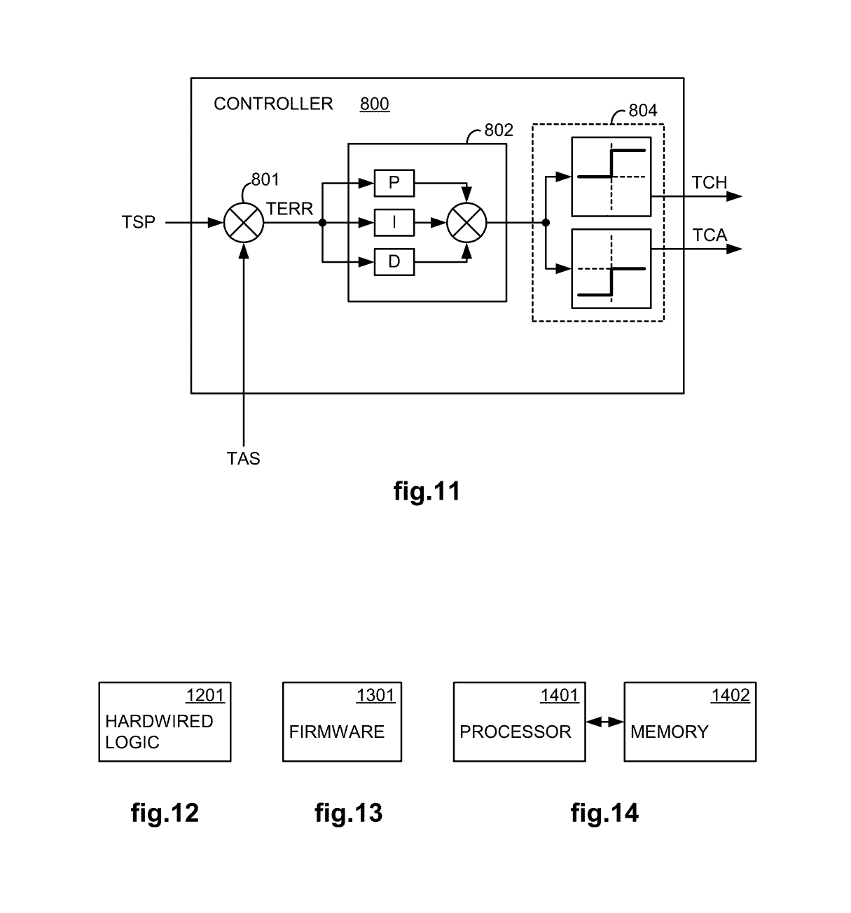

FIG. 11 illustrates, as an example, a block diagram of the controller 800. A node 801 receives the information of the setpoint temperature (TSP) and the information of the sensed temperature (TAS) and determines a temperature error (TERR) as the difference of the two according to the following equation:

TERR=TSP−TAS

The temperature error (TERR) is provided as an input to a Proportional, Integral, Derivative (PID) controller 802 which configured to generate positive output for positive error (TERR) and a negative output for a negative error (TERR). For descriptive purposes, the output of the PID controller 802 is shown as being connected to a pass-through function 804. The pass-through function 804 is characterized by its input being passed to a first output if the input is positive or its input being inverted and passed to a second output if the input is negative. The first output is used to generate the magnitude of the electrical command (TCH) for the heater 722 and the second output is used to generate the magnitude of the pressure command (TCA) for the internal actuator 740. Thus, when the sensed temperature (TAS) of the thermal plate 720 is less than the setpoint temperature (TSP), the temperature error TERR is positive and the heater 722 is controlled by the PID controller 802 to heat up the thermal plate 720. In this first case, the controller 800 would preferably release any pressure in the piston of the pneumatic actuator 740. On the other hand, when the sensed temperature (TAS) of the thermal plate 720 is greater than the setpoint temperature (TSP), the temperature error TERR is negative and the pneumatic actuator 740 is controlled by the PID controller 802 to cool down the thermal plate 720. In this second case, the controller 800 would preferably turn off any electrical power being provided to the heater 722. Finally, if the sensed temperature (TAS) of the thermal plate 720 is equal to the setpoint temperature (TSP), then the controller 800 preferably releases any pressure in the piston of the pneumatic actuator 740 and turns off any electrical power being provided to the heater 722, because the temperature error TERR is zero.

The controller 800 is implemented as one or more electronic devices mounted on a printed circuit board in the control box 950. Although a PID controller 802 is described, it is to be appreciated that other conventional control laws may be alternatively used in the controller 800 and are contemplated to be fully within the scope of the present invention. As respectively depicted in FIGS. 12-14, the controller 800 may be implemented using any one of hardwired logic 1201, firmware 1301, a processor 1401 coupled to a memory 1402, or any combination of hardwired logic, firmware, processor, and memory. With regards to the embodiment depicted in FIG. 14, the processor 1401 executes program instructions which are non-transitorily stored in the memory 1402 to implement the described functions of the controller 800.

The temperature of the DUT 200 is determined by the ambient temperature and the heat which is generated by, provided to, and/or absorbed from the DUT 200. The DUT 200 generates heat (TDUT) through resistive heating as current signals pass through its electronic circuitry during the testing of the DUT 200. When the heater 722 is energized, the heater 722 provides heat (TH) to the DUT 200 through the thermal plate 720. When the internal actuator 740 is sufficiently actuated (as explained below), the cold head 710 absorbs heat from the DUT 200 through the thermal plate 720. The temperature of the DUT 200 and the temperature of the thermal plate 720 are related through laws of thermodynamics. Therefore, the temperature sensor 724, which senses the temperature (TA) of the thermal plate 720, is also effectively sensing the temperature of the DUT 200 at that time.

The heat (TC) being absorbed from the DUT 200 (through the thermal plate 720) by the cold head 710 is a function of the temperature of the cold head 710 and the thermal conductance between the cold head 710 and the thermal plate 720. As explained above, the temperature of the cold head 710 is controlled by a refrigeration loop 970 that cycles refrigerant through the cold head 710 as part of a refrigeration system. The thermal conductance between the cold head 710 and the thermal plate 720, as will be explained below, is determined by the downward force that the internal actuator 740 is applying against the internal pusher plate 741.

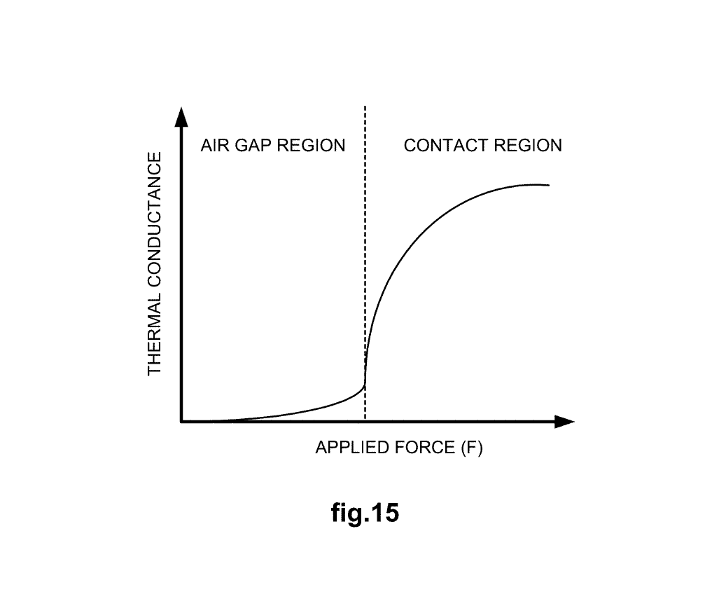

FIG. 15 illustrates, as an example, a thermal conductance versus applied force (F) relationship that determines the value for the thermal conductance that affects the absorption of heat (TC) by the cold head 710 from the thermal plate 720. The force (F) in this case is a difference between the downward force (F_{ACT}) being exerted by the internal actuator 740 against the internal pusher plate 741 and the opposing (upward) force (F_{SPR}) exerted by the bias springs 744, wherein the force (F_{SPR}) exerted by the bias springs is characterized by a spring constant (K) and the change in compression (ΔZ) of the bias springs as measured along the vertical (Z-axis) direction.

F=F_{ACT}−K(ΔZ)

When the internal actuator 740 is not generating a downward force against the internal pusher plate 741, the primary force being exerted against the bias springs 744 is the weight of the block 742. Therefore, the maximum gap 745 that occurs when the internal actuator 740 is not generating a downward force can be determined by subtracting the change in compression (ΔZ_{BLK}) due to the weight of the block and the offset (L_{OS}) between the top of the thermal plate 720 and the bottom of the inner surface of the housing 732 from the length (L_{SPR}) of the uncompressed spring.

Gap_{MAX}=L_{SPR}−ΔZ_{BLK}−L_{OS}

While adjoining surfaces of the cold head 710 and thermal plate 720 are making physical contact, the pressure (P) being applied by the bottom surface of the cold head 710 against the top surface of the thermal plate 720 is the force (F) spread out over an area of the bottom surface of the cold plate 710 that is in contact with the top surface of the thermal plate 720.

P=F÷AREA_{CT/TP}

As indicated in FIG. 15, the thermal conductance versus force relationship is characterized in two distinct regions. A first region is denoted as the “Air Gap Region” and a second region is denoted as the “Contact Region.” In the “Air Gap Region”, the force (F) may be increased until the bias spring is compressed to the point where the bottom surface of the cold head 710 makes physical contact with the top surface of the thermal plate 720 (i.e., until the gap between the two is zero). In this region, the thermal conductance increases, according to the thermal conductivity of air, as the bottom surface of the cold head 710 approaches the top surface of the thermal plate 720.

In the “Contact Region”, the thermal conductance is determined by the magnitude of the contact pressure (P) that the cold head 710 is applying against the thermal plate 720. The thermal conductance in this case is known to increase asymptotically with increasing applied pressure. A summary of empirical results for various materials is tabulated and theoretically explained, for example, in NASA Technical Memorandum 110429, authored by Louis J. Salerno and Peter Kittel, Ames Research Center, Moffett Field, California, entitled “Thermal Contact Conductance”, and dated February 1997, details of which are incorporated herein by reference.

FIG. 16 illustrates, as an idealized example for explanation purposes, a partial cross-sectional view of adjoining surfaces, 1601 and 1602, respectively of the cold head 710 and the thermal plate 720. In the idealized example, three points of contact between the cold head 710 and the thermal plate 720 are depicted. In the first point of contact, the highest peaks (e.g., C1 and T1) make physical contact so that there is limited thermal conductance between the cold head 710 and the thermal plate 720. In the second point of contact, the highest peaks are assumed to still make physical contact and now intermediate peaks (e.g., C2 and T2) also make physical contact so that there is more thermal conductance between the cold head 710 and the thermal plate 720. In the third point of contact, the highest and intermediate peaks are assumed to still make physical contact and now lower peaks (e.g., C3 and T3) also make physical contact so that there is even more thermal conductance between the cold head 710 and the thermal plate 720. As should be appreciated, the surface topographies are chosen in this idealized example for easier explanation.

Although the idealized example is useful for understanding why the thermal contact conductance changes with applied pressure, the deformation of the higher peaks as contact pressure is increased to reach lower peaks occurs almost in molecular scale (e.g., the thermal plate 720 preferably has a mirror finish on its top surface), so that the deformation will behave differently from how one might perceive it would occur with larger rough surfaces. Consequently, except for a virgin run where the thermal conductance versus force/pressure relationship may be slightly different, the relationship will settle to provide repeatable results in subsequent applications of contact pressure.

Thus, the thermal forcing system 900 differs significantly from the previously described prior art thermal forcing systems by employing a movable cold head (evaporator) relative to a thermal plate to control the heat absorption (cooling) of a device under test which is thermally coupled to the thermal plate. In particular, in prior art thermal forcing systems, the cold head is stationary relative to the thermal plate and it is always making physical contact with the thermal plate. Thus, in order to control heat absorption, either the temperature of the cold head is controlled, for example by adjusting the flow rate of the refrigerant, or the power provided to a thermoelectric cooler (TEC), which is disposed between the cold head and the thermal plate, is controlled to adjust a temperature differential between opposing faces of the TEC.

However, the prior art approach of controlling the temperature of the cold head (evaporator) by adjusting the flow rate of the refrigerant results in undesirable delay between the time that the refrigerant flow rate is changed and the time that the desired heat absorption rate at the cold head (evaporator) is achieved. In contrast, the thermal forcing system 900 almost immediately adjusts the heat absorption rate of the cold head by simply moving the cold head away from or towards the thermal plate without having to change the nominal temperature of the cold head (evaporator).

In addition, the prior art approach of interposing a TEC between the cold head and the thermal plate may present a problem if the system's cooling capacity is being bottlenecked by the heat transfer capacity of the TEC. This is in addition to other known deficiencies for Peltier devices, as described previously.

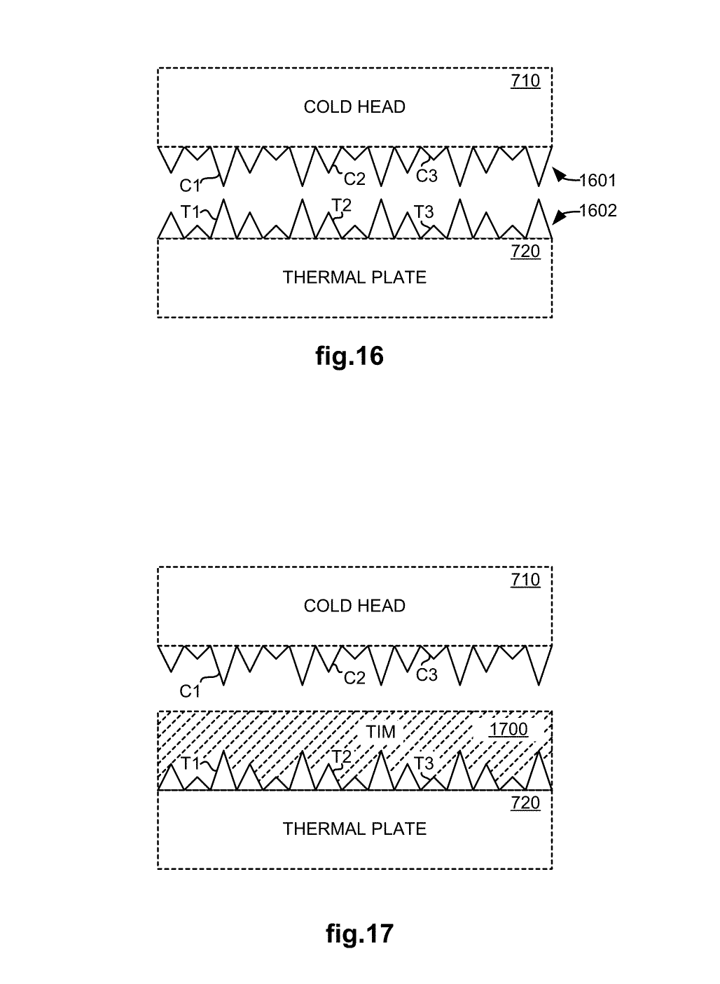

FIG. 17 illustrates a partial cross-sectional view of adjoining surface of a cold head and thermal plate, with a layer of Thermal Interface Material (TIM) 1700 disposed on the top surface of the thermal plate 720. Such a layer of TIM may be beneficial for a number of reasons. For example, it may be useful to avoid the moving cold head 710 from being stuck on to the top surface of the thermal plate 720. Also, it may improve the thermal conductance between the contact surfaces. The layer of TIM may particularly be useful when the contact surfaces are not perfectly flat due to micro gaps or they are not perfectly in parallel. Typically, such a TIM layer 1700 is relatively thin (e.g., 0.1 millimeters thickness), so that its application does not significantly change the thermal conductance versus force/pressure function except to slightly improve the thermal conductance.

Although the various aspects of the present invention have been described with respect to an embodiment, it will be understood that the invention is entitled to full protection within the full scope of the appended claims.

What is claimed is:

1. A thermal forcing system for controlling a temperature of a device under test, the thermal forcing system comprising:
a thermal plate that is thermally coupleable to the device under test;
a temperature sensor that senses a temperature of the thermal plate;
a cold head that has a temperature which is lower than the temperature of the thermal plate;
an actuator coupled to the cold head; and
a controller configured to:
receive information of the temperature sensed by the temperature sensor;
determine a temperature difference between a setpoint temperature and the temperature sensed by the temperature sensor; and
command the actuator to move the cold head relative to the thermal plate in response to the temperature difference, so as to facilitate adjusting the temperature of the thermal plate to the setpoint temperature.

2. The thermal forcing system of claim 1,
wherein the controller is configured to command the actuator to move the cold head relative to the thermal plate in response to the temperature difference, so as to facilitate adjusting the temperature of the thermal plate to the setpoint temperature, by:
conditioned upon a surface of the cold head physically contacting a surface of the thermal plate:
adjustably applying contact pressure by the surface of the cold head against the surface of the thermal plate according to a thermal conductance versus contact pressure relationship that is characterized by topographies of the physically contacting surfaces of the cold head and the thermal plate.

3. The thermal forcing system of claim 2,
wherein the thermal contact conductance increases asymptotically as the contact pressure being applied against the thermal plate by the cold head increases.

4. The thermal forcing system of claim 1,
wherein the controller is configured to command the actuator to move the cold head relative to the thermal plate in response to the temperature difference, so as to facilitate adjusting the temperature of the thermal plate to the setpoint temperature, by:
conditioned upon a surface of the cold head not physically contacting a surface of the thermal plate so as to be separated by a gap:
adjusting the gap between the cold head and the thermal plate.

5. The thermal forcing system of claim 4, further comprising:
a bias spring that is mechanically coupled to the cold plate and the thermal plate, so that the bias spring exerts a spring force that causes a bias gap between the cold head and the thermal plate when the actuator is not being actuated to move the cold head relative to the thermal plate; and
wherein the controller is configured to adjust the gap between the cold head and the thermal plate by:
commanding the actuator to move the cold head relative to the thermal plate subject to the spring force.

6. The thermal control unit of claim 1, further comprising:
a refrigerant;
a compressor; and
a condenser;
wherein the cold head includes an evaporator that cooperates with the compressor and the condenser to cycle the refrigerant so that the cold head has the temperature that is lower than the temperature of the thermal plate.

7. The thermal forcing system of claim 1, further comprising:
a heater thermally coupled to the thermal plate;
wherein the controller is configured to command the heater to produce a magnitude of thermal energy and command the actuator to move the cold head relative to the thermal plate in response to the temperature sensed by the temperature sensor, so as to facilitate adjusting the temperature of the thermal plate to the setpoint temperature.

8. The thermal forcing system of claim 1, further comprising:
a housing to which the thermal plate is secured, the housing enclosing the actuator and the cold head; and
an external actuator mechanically coupled to the housing and adapted to generate, upon actuation, a force against the housing sufficient to maintain physical contact between the thermal plate and the device under test, so that the thermal plate is thermally coupled to the device under test.

9. The thermal forcing system of claim 8,
wherein the actuator and the external actuator comprise pneumatic actuators.

10. A method for controlling a temperature of a device under test, the method comprising:
a controller receiving information of a temperature sensed by a temperature sensor that is thermally coupled through a thermal plate to the device under test;
the controller determining a temperature difference between a setpoint temperature and the temperature sensed by the temperature sensor; and
the controller commanding an actuator to move a cold head relative to the thermal plate in response to the temperature difference, so as to facilitate adjusting the temperature of the thermal plate to the setpoint temperature, wherein the cold head has a temperature that is less than a temperature of the thermal plate.

11. The method of claim 10,
wherein the controller commanding an actuator to move a cold head relative to the thermal plate in response to the temperature difference, so as to facilitate adjusting the temperature of the thermal plate to the setpoint temperature, comprises:
conditioned upon a surface of the cold head physically contacting a surface of the thermal plate:
the controller causing contact pressure by the surface of the cold head against the surface of the thermal plate to be adjustably applied according to a thermal conductance versus contact pressure relationship that is characterized by topographies of the physically contacting surfaces of the cold head and the thermal plate.

12. The method of claim 10,
wherein the controller commanding an actuator to move a cold head relative to the thermal plate in response to the temperature difference, so as to facilitate adjusting the temperature of the thermal plate to the setpoint temperature, comprises:
conditioned upon a surface of the cold head not physically contacting a surface of the thermal plate so as to be separated by a gap:
the controller causing the gap between the cold head and the thermal plate to be adjusted.

13. A thermal control unit for controlling a temperature of a device under test, the thermal control unit comprising:
a cold head including an evaporator for absorbing latent heat;
a thermal plate thermally coupleable to a device under test; and
an actuator mechanically coupled to the cold head for controllably moving the cold head relative to the thermal plate.

14. The thermal control unit of claim 13, further comprising:
a bias spring disposed relative to the cold head and the thermal plate so as to:
create a gap between the cold head and the thermal plate when the actuator is not controllably moving the cold head relative to the thermal plate, and
resist movement of the cold head towards the thermal plate.
